(19) United States
(12) Patent Application Publication
(10) Pub. No.: US 2012/0242515 A1
(43) Pub. Date: Sep. 27, 2012

(54) INDUCTIVE TOUCH SENSING CIRCUIT PROVIDING SENSITIVITY COMPENSATION

(75) Inventors: KEVIN LACEY, OAK PARK, IL (US); JAMES W. KOPEC, CAMPTON HILLS, IL (US)

(73) Assignee: DIEHL AKO STIFTUNG & CO. KG, WANGEN (DE)

(21) Appl. No.: 13/070,871

(22) Filed: Mar. 24, 2011

(51) Int. Cl. H03K 17/94

(52) U.S. Cl. 341/22

(57) ABSTRACT

An inductive touch sensing circuit having sensitivity compensation is provided. A digital processor controls a variable amplifier signal source that is synchronized to the key selection. This configuration provides closed loop control of the strength of each key's excitation signal for each of a plurality of inductive touch sensors or key switch assembly, so that the system can adaptively provide different strength excitation signals to each of the different key switch assemblies. In this way, the inductive touch sensing circuit can compensate for the effects of age, temperature, environment and varying key geometries and tolerances, using the excitation signal delivered by the drive circuit.

### FIELD OF THE INVENTION

The instant invention relates to an inductive touch sensing circuit and, more particularly, to an improved circuit that provides sensitivity compensation for such a sensing circuit.

### DESCRIPTION OF THE RELATED ART

Generally, inductive touch key switches and circuits are known. Such technology works with small spacing >1 mm and small movements of 0.1 mm. Sensitivity to initial build tolerance and changes from aging are a difficult problem. One example of such technology was published by MICROCHIP TECHNOLOGY INC. (“MICROCHIP”) of Chandler, Ariz. However, the circuit published by MICROCHIP had no provision for signal changes.

What is needed is an improved inductive touch sensing circuit design that can compensate for initial build tolerances and changes due to aging, such as relaxation of materials and stress inducted movements.

### SUMMARY OF THE INVENTION

It is accordingly an object of this invention to provide an inductive touch sensing circuit that overcomes the disadvantages of the prior art. More particularly, an inductive touch sensing circuit having sensitivity compensation is provided. In one particular embodiment of the invention, a digital processor controls a variable amplifier signal source that is synchronized to the key selection. This configuration provides closed loop control of the strength of the excitation signal for each of a plurality of inductive touch sensors or key switch assembly, so that the system can adaptively provide different strength excitation signals to each of the different key switch assemblies. In another particular embodiment, an automatic gain control (AGC) circuit and/or variable resistance circuits are used to adaptively tune the inductive touch sensing circuit to compensate for sensitivities due to manufacture, temperature, aging, etc.

Although the invention is illustrated and described herein as embodied in a system and/or circuit for providing sensitivity compensation for an inductive touch sensing circuit, it is nevertheless not intended to be limited to the details shown, since various modifications and structural changes may be made therein without departing from the spirit of the invention and within the scope and range of equivalents of the claims.

The construction of the invention, however, together with the additional objects and advantages thereof will be best understood from the following description of the specific embodiments when read in connection with the accompanying drawings.

### BRIEF DESCRIPTION OF THE DRAWINGS

The present invention is illustrated by way of example, and not by way of limitation, in the figures of the accompanying drawings, in which like reference numerals refer to similar elements and in which:

FIG. 1 is a block diagram of an inductive touch sensing circuit in accordance with the prior art;

FIG. 2 is a basic block diagram of a system for providing sensitivity compensation for an inductive touch sensing circuit in accordance with one particular embodiment of the invention

FIG. 3 is a circuit diagram of an inductive touch sensing circuit in accordance with one particular embodiment of the present invention;

FIG. 4 is a circuit diagram of an inductive touch sensing circuit in accordance with another particular embodiment of the present invention;

FIG. 5 is a circuit diagram of an inductive touch sensing circuit in accordance with a further particular embodiment of the present invention;

### DETAILED DESCRIPTION OF THE PREFERRED EMBODIMENTS

An inductive touch system and sensing circuit for use in such a system is disclosed herein. The system of the invention can be used to provide sensitivity compensation in an inductive key switch circuit, such as that published by MICROCHIP.

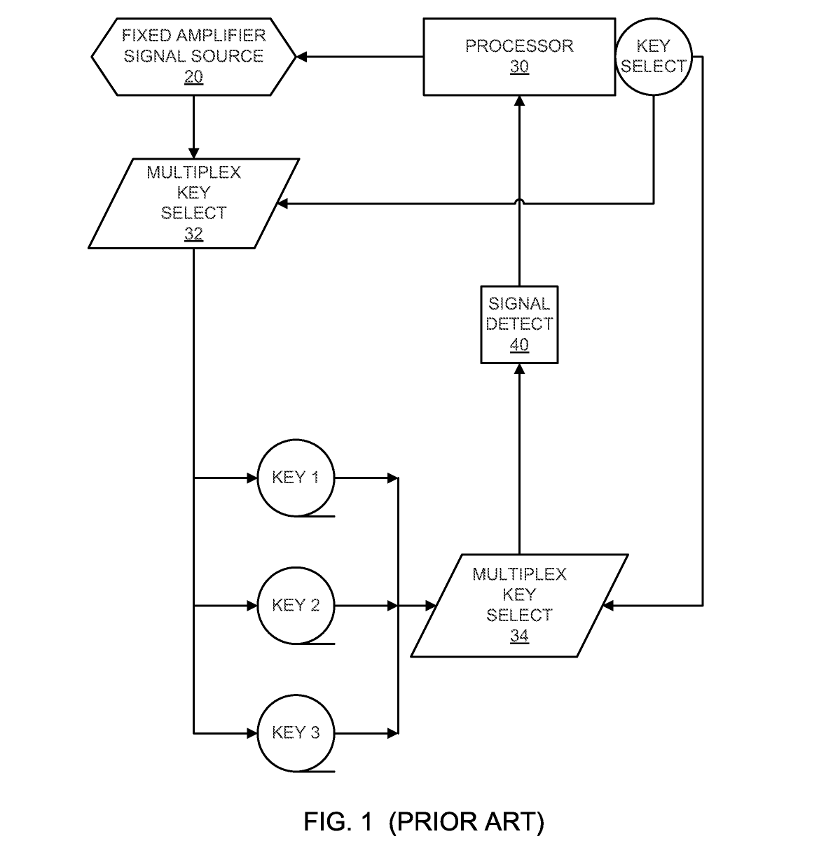

Referring more particularly to FIG. 1, there is shown a block diagram of a prior art inductive touch sensing system 10 for providing inductive touch sensing. An inductive sensing system of this type is disclosed in U. S. Patent Application Publication Nos. 2010/0090716 and 2010/0090717 to Steedman et al., those patent application publications being incorporated herein, by reference, for all that they teach. A digital processor 30 provides clock and control functions for the system 10. The digital processor 30 may be any known type of digital processor that is programmable and/or executes instructions stored in a program memory, such as a microcontroller, microprocessor, microcomputer, digital signal processor (DSP), application specific integrated circuit (ASIC), programmable logic array (PLA), etc.

The digital processor 30 of the system 10 controls the sequential excitation of the inductive touch sensors or key switch assemblies, key 1, key 2, key 3, and detection of any output signals therefrom by the signal detector 40, using the multiplexers 32, 34, as described, for example, in paragraphs [0024]-[0025] of U. S. Patent Application Publication No. 2010/0090716. In particular, in the system 10, a fixed signal source 20 (i.e., producing a fixed strength signal) is used to drive or sequentially excite the key switch assemblies (key 1, key 2, key 3). One particular example of inductive touch sensors or key switch assemblies that can be used in the circuit 10 are the Microchip inductive mTouch™ sensors, produced by MICROCHIP.

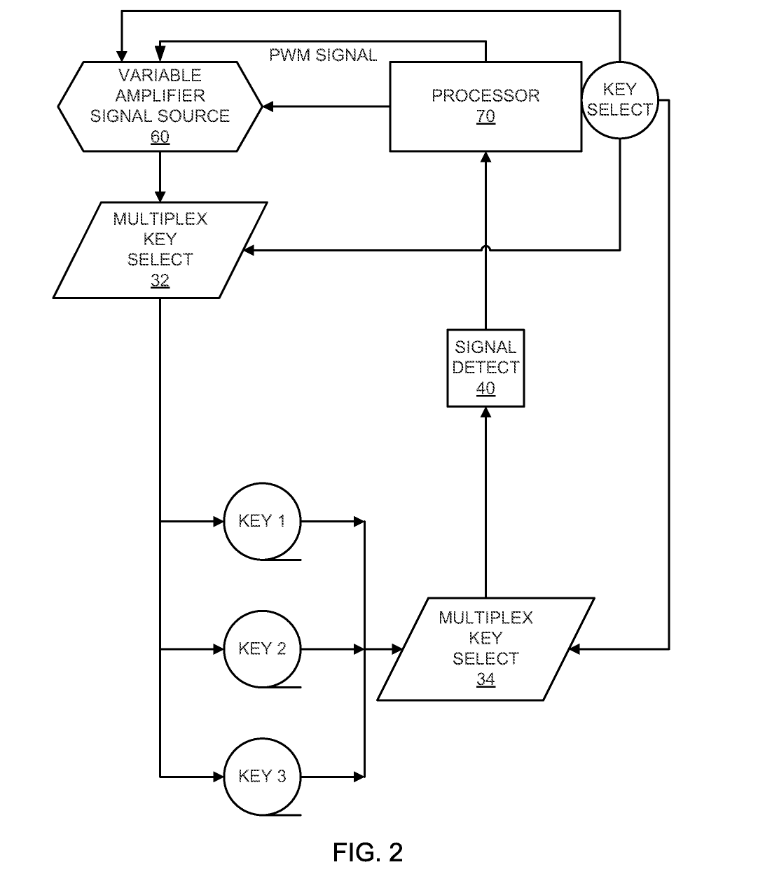

Referring now to FIG. 2, there is shown a block diagram for an inductive touch sensing system 50 that provides sensitivity compensation in accordance with one particular embodiment of the invention. The system 50 includes that are functionally equivalent to those discussed in connection with system 10 of FIG. 1 with the exception that, in the system 50, the fixed amplifier signal source 20 of FIG. 1 has been replaced by a variable amplifier signal source 60 synchronized to the key selection, as shown. This configuration permits closed loop control of the strength of the excitation signal for each inductive touch sensor or key switch assembly, key 1, key 2, key 3, based on the drive signal provided by the variable amplifier signal source 60. Thus, the system 50 of FIG. 2 can provide different strength (i.e., levels of) excitation signals to different key switch assemblies. The digital processor 70 controls the variable amplifier signal source 60 using, for example, a pulse width modulated (PWM) output from the processor that is additionally provided to the variable amplifier signal source 60.

In this way, the system 50 can compensate for the effects of age, temperature, environment and varying key geometries and tolerances, using the excitation signal, rather than in the detection signal from each key. There is a narrow range of excitation signal that allows for the best detection in an inductive key switch system. The system 50 of FIG. 2 allows for greater variation in a design for key size spacing and/or conductor spacing that is not possible with the fixed amplifier signal source 20 of the system 10 of FIG. 1.

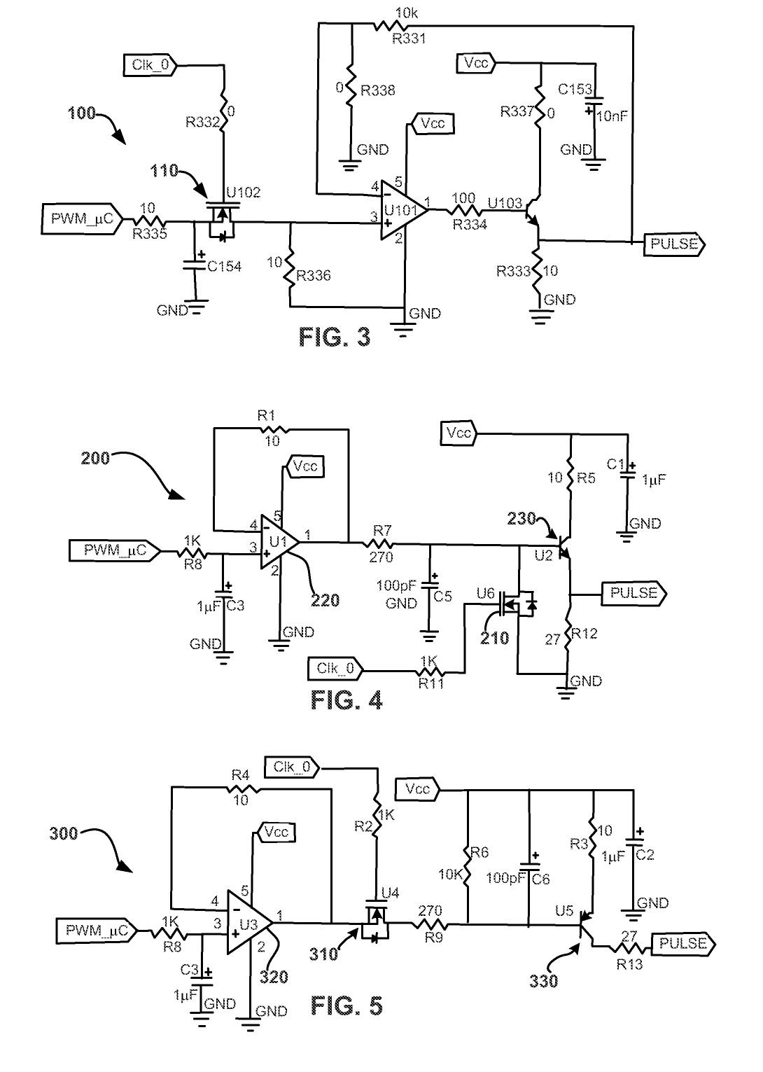

Referring now to FIGS. 2 and 3, there is shown a circuit 100, in accordance with a first particular preferred embodiment of the invention, which can be used as the variable amplifier signal source 60 in the system 50 of FIG. 2. The circuit 100 was designed for simplicity and low cost. A field effect transistor (FET) 110 acts as a switch controlled by a gate input of pulses from a clock signal (clk_0) from the digital processor 70 of FIG. 2. The drive source to the FET 110 is a variable DC voltage generated by a PWM signal from the digital processor 70 of FIG. 2. An operational amplifier or op amp 120 and transistor 130 act as an impedance buffer, so that little current is drawn from the PWM signal and that the output impedance is low. In the presently disclosed embodiment, the transistor 130 was selected to be an NPN transistor. However, it would be apparent to a person skilled in the art that a PNP transistor could be used with only minor circuit redesign. The elements 120 and 130 act together to form, essentially, a voltage follower in the current configuration.

In use, the circuit 100 can be provided in the system 50 of FIG. 2, in place of the variable amplifier signal source 60 to dynamically provide a range of excitation signal strengths to the individual key switch assemblies. Although not shown, one or more additional FETs can be connected to the positive terminal of the op amp 120 to enable faster switching between key strengths.

Referring now to FIGS. 2 and 4, there will be described another embodiment of an inductive touch sensing circuit 200 that provides compensation for sensitivities due to age and/or manufacturing tolerances, etc. More particularly, as with the previous embodiment, a PWM signal from the digital processor 70 is input to the circuit 200, wherein the resistor R8 and capacitor C3 convert the PWM signal from the digital processor 70 into a DC voltage. The DC voltage is provided to the + input of an operational amplifier or op amp 220. The output from the op amp 220 is a DC voltage equal to that which was input to the op amp 22, with only ripple from the PWM. However, the output of the op amp 22 has a lower impedance than the input, since the op amp 220 is configured as a voltage follower, i.e., with the resistor R1 acting as a stability resistance. Resistor R7 and capacitor C5 remove some more ripple, and create a solid DC voltage at the base of the transistor 230. Transistor 230 is additionally configured as a voltage follower. The base of the transistor 230 is tied to the drain of a field effect transistor (FET) 210. As such, the transistor 230 is switched on and off by the operation of the FET 210, in response to the clocking signal clk_0 on the gate of the FET 210. More particularly, when the FET 210 is on, the transistor 230 is off. When the FET 210 is off, the base of the transistor 230 is at the DC voltage out from the op amp 220 and the emitter of the transistor 230 is at −0.7 V. This creates a variable strength pulse that is used to excite a coil of an inductive switch assembly.

In the circuit 200, feedback is simplified by using the PWM output signal from the digital processor 70. A control loop can be established in a several ways. For example, a software control loop (i.e., with software executed on the digital processor 70) can be made with a separate loop for gain, based on long term signal averaging. It may also be possible to regulate the signal to a constant strength by varying the PWM signal provided by the digital processor 70. The PWM signal is then input to filters and key detection circuitry.

Referring now to FIGS. 2 and 5, there is provided a further embodiment of an inductive touch sensing circuit that provides a variable amplifier signal source circuit 300 in accordance with the present invention. In the present embodiment, an operational amplifier or op amp 320 is configured substantially as described in connection with FIG. 4, discussed hereinabove. However, in the instant embodiment, the FET 310 has been located after the op amp 320, so as to directly drive the switching transistor 330. More particularly, the drain of the FET 310 is connected to the base of the transistor 330. In the instant embodiment, the transistor 330 was chosen to be a PNP transistor, to avoid a voltage loss of base-emitter that occurs in an NPN transistor. As a result of this configuration, there is an inversion, but the pulse duty cycle is 50%, so the inversion is not important to the operation.

Note that the foregoing embodiments can be modified, if desired, and still remain within the scope and spirit of the present invention. For example, if desired, the circuits of the instant invention can be modified to include more than one PWM signal from the digital processor, wherein an average the signals the signals are averaged and summed. In this way, other hardware control loops can be incorporated; for instance, where there is more than one key switch assembly, and the difference in key characteristics is large.

The foregoing description of the invention has shown that an automatic gain control (AGC) circuit and/or variable resistance circuits can be used to adaptively tune the inductive touch sensing circuit to compensate for sensitivities due to manufacture, temperature, aging, etc.

Although the invention is illustrated and described herein as embodied in a system and circuit for sensitivity compensation in an inductive touch sensing circuit, it is nevertheless not intended to be limited to only these details shown. As can be seen, various modifications and structural changes may be made therein without departing from the spirit of the invention and within the scope and range of equivalents of the claims.

What is claimed is:

1. An inductive touch sensing system, comprising:
at least one inductive touch key switch assembly;
a variable amplifier signal source providing a drive signal to the at least one inductive touch key switch assembly; and
a detection circuit for detecting a signal indicative of a key switch actuation at the at least one inductive touch key switch assembly.

2. The inductive touch sensing system of claim 1, wherein the variable amplifier signal source is configured to use feedback to adaptively adjust the level of the drive signal provided to the at least one inductive touch key switch assembly.

3. The inductive touch sensing system of claim 1, further including:
at least a second inductive touch key switch assembly;
a key selector for sequentially selecting the at least one inductive touch key switch assembly and the at least a second inductive touch key switch assembly for receiving a drive signal from said variable amplifier signal source; and
said variable amplifier signal source being synchronized with said key selector to provide an adaptively adjusted drive signal to the particular one of the at least one inductive touch key switch assembly and the at least a second inductive touch key switch assembly selected by the key selector.

4. The inductive touch sensing system of claim 3, wherein the variable amplifier signal source is configured to use feedback to produce said adaptively adjusted drive signal.

5. The inductive touch sensing system of claim 4, wherein the variable amplifier signal source includes an operational amplifier configured to include a feedback loop.

6. The inductive touch sensing system of claim 3, wherein the variable amplifier signal source provides an adaptively adjusted drive signal to the at least one inductive touch key switch assembly that is of a different signal strength than the adaptively adjusted drive signal provided to the at least a second inductive touch key switch assembly.

7. The inductive touch sensing system of claim 1, wherein the variable amplifier signal source is controlled by a processor.

8. The inductive touch sensing system of claim 7, wherein said processor controls the variable amplifier signal source using a control signal provided from the processor to the variable amplifier signal source.

9. The inductive touch sensing system of claim 8, wherein said control signal is a pulse width modulated (PWM) output from the processor to the variable amplifier signal source.

10. An inductive touch sensing system, comprising:
a processor;
at least one inductive touch key switch assembly;
a drive signal circuit receiving a first input signal and a second input signal from the processor and providing a drive signal to the at least one inductive touch key switch assembly;
the drive signal circuit using feedback to adaptively adjust the level of the drive signal provided to the at least one inductive touch key switch assembly; and
a detection circuit for detecting a signal indicative of a key switch actuation at the inductive touch key switch assembly.

11. The inductive touch sensing system of claim 10, wherein the first input signal is a clock signal.

12. The inductive touch sensing system of claim 10, wherein the second input signal is a pulse width modulated (PWM) signal.

13. The inductive touch sensing system of claim 10, wherein the first input signal controls the state of a switch in said drive signal circuit that provides a signal generated from said second input signal to an amplifier in said drive signal circuit.

14. The inductive touch sensing system of claim 13, further including at least a second inductive touch key switch assembly, the first input signal controlling a selection of one of the at least one inductive touch key switch assembly and the at least a second inductive touch key switch assembly.

15. A method for performing inductive touch sensing, comprising the steps of:
providing a first adaptively adjusted drive signal to at least one inductive touch key switch assembly; and
detecting a signal indicative of a key switch actuation at the at least one inductive touch key switch assembly.

16. The method of claim 15, wherein a variable amplifier signal source is configured to use feedback to adaptively adjust the level of the first adaptively adjusted drive signal provided to the at least one inductive touch key switch assembly.

17. The method of claim 16, wherein the variable amplifier signal source includes an operational amplifier configured to include a feedback loop.

18. The method of claim 15, further including:
selectively providing a second adaptively adjusted drive signal to at least a second inductive touch key switch assembly;

19. The method of claim 18, wherein the first adaptively adjusted drive signal is of a different signal strength than the second adaptively adjusted drive signal.

20. The method of claim 19, wherein a first signal from a processor is used to select between providing the first adaptively adjusted drive signal to the at least one inductive touch key switch assembly and the second adaptively adjusted drive signal to the at least a second inductive touch key switch assembly.
